(19) United States
(12) Patent Application Publication
(10) Pub. No.: US 2004/0190274 A1
(43) Pub. Date: Sep. 30, 2004

(54) Compact low cost plastic MCM to PCB

(76) Inventors: Yoshio Saito, Los Angeles, CA (US); Thomas J. Estes, Los Angeles, CA (US); John J. Berenz, San Pedro, CA (US)

Correspondence Address: Northrop Grumman Space & Mission Systems Corp., Intellectual Asset Management, Patent Counsel, R11/2796, One Space Park, Redondo Beach, CA, 90278, US

(21) Appl. No.: 10/400,771

(22) Filed: Mar. 27, 2003

(51) Int. Cl. H01L 27/14

(52) U.S. Cl. 361/783

(57) ABSTRACT

The present invention relates to a system and methodology to reduce size, weight and cost, improve data processing rates and serviceability, and accommodate higher I/O multi-chip modules (MCMs) for printed circuit board (PCB) assemblies employed in the electronics industry. This is accomplished by selecting low cost, pre-assembled, plastic chip type MCMs for constructing a daughter card where the daughter card material can accommodate high density lines and spaces. Optical interconnects are employed between the daughter card and the motherboard to provide a high speed interface that is substantially not effected by contaminates or limitations associated with electrical lead wires and solder bonds. The result is a high performance card that meets current and projected future demands in signal processing.

### BACKGROUND OF THE INVENTION

1. Field of the Invention

The present invention relates to a system and methodology for signal processing, and in particular to a compact, low cost, plastic multi-chip module (p-MCM) daughter board operatively coupled to a printed circuit board (PCB) for signal processing in the aerospace industry.

2. Discussion of the Related Art

The evolution in electrical/electronical technologies has embedded signal processing with substantially every aspect of contemporary culture. Generally, any device that requires analog, digital and/or radio frequency (RF) signals to be processed employs signal processing. This marriage of signal processing and society has lead to breakthroughs and discoveries in areas dependent on information gathered through signal characteristics.

Several examples of utilities that employ signal processing include personal computers (PCs), automobiles, cell phones, aircraft, satellite and spacecraft. Personal computers have become indispensable household items. They are utilized for managing finances, controlling security, heating and lighting systems, providing entertainment, preparing meals (e.g., the microwave) and bridging people to the endless amount of information available through the Internet. In the workplace, they are powerful engines for solving problems and developing technologies that improve the standard of living of humanity.

In automobiles, signal processors control ignition systems (e.g., fuel injection and timing), provide diagnostics (e.g., oil pressure, water temperature and fuel levels) and ensure safety (e.g., door ajar and seat belt not fastened). They can also be employed in navigation and roadside emergency systems. Signal processors in cell phones provide the ability to communicate (e.g., voice and text messaging) and retrieve information (e.g., stock quotes) internationally.

Advances in signal processing are readily apparent in the aerospace industry. Some aerospace manufacturers employ signal processing instrumentation on board fixed wing aircraft for applications such as land surveying. Collected data is then processed to create video data offering a superb dynamic range. Data collection is performed with image spatial resolutions spanning from less than 1 meter to more than 11 meters, with spectral coverage from 380 to 2450 nm. Spectral resolution is about 5.25 nm in the visible/near infrared (380-1000 nm) and about 6.25 in the short wave infrared (1000-2450 nm).

Other systems contain finely tuned sensors that are coupled with powerful signal processing algorithms to provide a tool in spectral bands applications. For example, these systems can process reflected light, most of which registers in wavelengths, or bands, invisible to humans, to create a unique spectral footprint for objects such as soil, water, trees, vegetation, structures, metals, paints and fabrics. The unique spectral footprint can then be used for precision discrimination, for example determining whether a tree is a maple or an oak.

Industry and consumer demand for more powerful, faster, smaller, and less expensive processors and peripherals has driven the technology industry to produce generation after generation of processing devices. However, Integrated circuit (IC) technology and system infrastructures for connecting these devices to each other and to peripherals has not kept pace with the data transfer demands. As a result, overall system performance often suffers from bottlenecks in interconnections.

Several factors have exaggerated this problem in embedded systems. In one example, the role of the backplane is shifting from its traditional task of providing a data-flow channel between boards to that of handling control, status, and initialization tasks. Even though some newer high-speed backplane technologies are emerging, the concept of arbitrating for a common bus shared across multiple boards proves limiting in the more demanding applications. As a result, alternate techniques for moving data across the backplane have grown in acceptance.

### BRIEF SUMMARY OF THE INVENTION

The present invention relates to a system and methodology to reduce size, weight and cost associated with electronic packaging/interfacing between one or more Multi Chip Modules (MCM) and a related processing and/or communications architecture. Multi Chip Modules adapted in accordance with the present invention improve data processing rates, system scalability and serviceability while accommodating higher input/output (I/O) integrated circuits (ICs) for printed circuit board (PCB) assemblies employed in the aerospace or other communications industries. One or more of these aspects can be achieved by modularizing signal processing hardware and firmware on compact removable subunits or modules which can be represented by the MCM. Respective modules can be constructed with laminated materials that can accommodate smaller signal line dimensions and spacing there between to facilitate dense input/output (I/O) channels or configurations. Such construction facilitates lower cost utilization of plastic integrated circuits in one example,—in lieu of ceramic packages that have been conventionally applied. Similarly, MCM components can be selected based on materials, performance and layout configurations having attributes that include low cost, high speed, scalability and serviceability.

In another aspect of the present invention, the MCM and motherboard interface through high-speed, optical technology to mitigate electrical signal problems and costs associated with hard-wired connections. Such signal problems can include degradation of signal performance as communications frequencies are increased, which are generally transparent to optical communications provided in accordance with the present invention. Aggregation of the aforementioned design considerations provides a flexible architecture that can overcome electrical component mounting and interconnect deficiencies, while scaling with future technology to achieve reduced size, weight, and cost and yet, facilitating increased communications performance.

The following description and the annexed drawings set forth in detail certain illustrative aspects of the invention. These aspects are indicative, however, of but a few of the various ways in which the principles of the invention may be employed and the present invention is intended to include all such aspects and their equivalents. Other advantages and novel features of the invention will become apparent from the following detailed description of the invention when considered in conjunction with the drawings.

### BRIEF DESCRIPTION OF THE DRAWINGS

FIG. 1 is a block diagram of a signal processing system in accordance with an aspect of the present invention.

FIG. 2 illustrates a signal processing system employing a client-host in accordance with an aspect of the present invention.

FIG. 3 is a block diagram illustration of a modulator/demodulator utilized with a signal processing system in accordance with an aspect of the present invention.

FIG. 4 depicts an exemplary expansion card in accordance with the present invention.

FIG. 5A is a block diagram of a signal processing system employing diagnostics in accordance with an aspect of the present invention.

FIG. 5B is an exemplary board level diagnostics method for a signal processing system in accordance with an aspect of the present invention.

FIG. 6 is a block diagram showing of a plurality of daughter cards interconnected to a signal processing system through an optical backplane in accordance with an aspect of the present invention.

FIG. 7 presents a top view illustration of an exemplary expansion card in accordance with the present invention.

FIG. 8 portrays an illustration of an exemplary expansion card mounted to a motherboard in accordance with the present invention.

FIG. 9 provides a side view illustration of an exemplary expansion card in accordance with the present invention.

FIG. 10 illustrates exemplary perpendicular connections between daughter cards and a motherboard in accordance with an aspect of the present invention.

FIG. 11 presents an exemplary stacked board method of connecting daughter boards to a mother board in accordance with an aspect of the present invention.

FIG. 12 illustrates an exemplary Free Space Optical Interconnect in accordance with an aspect of the present invention.

FIG. 13 presents a cross-sectional view of an exemplary expansion board mounting technique in accordance with an aspect of the present invention.

FIG. 14 provides a comparative example of a prior art technique for mounting expansion boards.

FIG. 15 is methodology for constructing a low cost, serviceable, improved performance signal processing system in accordance with an aspect of the present invention.

FIG. 16 illustrates an example operating environment in which the present invention may function in accordance with an aspect of the present invention.

### DETAILED DESCRIPTION OF INVENTION

The present invention is now described with reference to the drawings, wherein like reference numerals are used to refer to like elements throughout. In the following description, for purposes of explanation, numerous specific details are set forth in order to provide a thorough understanding of the present invention. It may be evident, however, that the present invention may be practiced without these specific details. In other instances, well-known structures and devices are shown in block diagram form in order to facilitate describing the present invention.

The subject invention relates to a system and methodology to reduce size, weight and cost, improve data processing rates, system scalability and serviceability and accommodate higher 10 integrated circuits (ICs) for printed circuit board (PCB) assemblies. This can be achieved by modularizing signal processing hardware and firmware on compact removable subunits or modules. Respective modules can be constructed with materials that accommodate dense input/output (10) channels. Components can be selected based on materials, performance and layout configurations having attributes that provide low cost, high speed, scalability and serviceability. A module is operatively coupled to a main processing board, or motherboard, via various interfaces and/or mediums such as high-speed optical communications to facilitate installation, removal and replacement.

As used in this application, the terms “component” and “system” are intended to refer to a signal processing/communications related entity, either hardware, a combination of hardware and software, software, or software in execution. For example, a component may be, but is not limited to being, an integrated circuit integral to a signal processor, a signal processor, an interconnection, a client/host, modulator, a thread of execution, a program, and/or a computer. By way of illustration, both the signal processing algorithm running on a signal processing chip and the signal processing chip can be a component. Additionally, one or more components may reside within a process and/or thread of execution and a component may be localized on one computer and/or distributed between two or more computers.

Further, a “daughter board” and “daughter card” refers to a printed circuit board that plugs into and extends the circuitry of another circuit board, for example a motherboard or another daughter board. It is an expansion board that accesses the motherboard components, for example memory and CPU, instead of sending data through an expansion bus. A “Mezzanine” daughterboard usually refers to a board that is installed in the same plane as but on a second level above the motherboard.

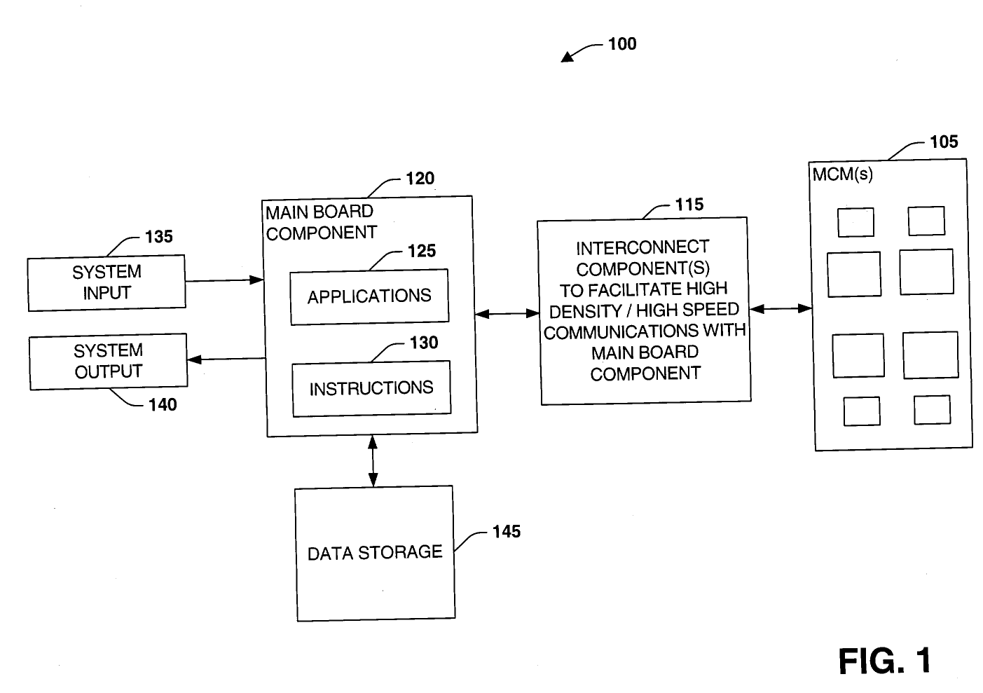

Referring initially to FIG. 1, a signal processing system 100 is illustrated in accordance with an aspect of the present invention. The signal processing system 100 facilitates high density component architectures and mitigates costs via one or more Multi Chip Modules 105 (MCM or MCMs) that support integrated circuit components, for example, and high speed couplings which are described and illustrated in more detail below. Generally, the MCM 105 is substantially smaller than conventional modules or boards, yet accommodates higher device and/or input/output (I/O) densities. For example, where conventional boards may be about 20″×26″, the MCM 105, in accordance with the present invention, may be about 1″×2″, wherein weight reduction can be achieved through several processes.

In one aspect, MCM 105 fabrication materials can lessen per board cost. In order to realize smaller chips having greater I/O capacity, BT (Bismaleimide Triazine) Laminate (e.g., micro via technology), or other circuit material can be employed as substrate material for the MCM 105. One advantage of BT Laminate is that it allows more I/O per area through reduced lines and spacing to facilitate a more compact circuit layout. For example, current printed circuit board (PCB) technology is typically limited to 5-mil lines and spaces, whereas BT Laminate facilitates less than 5-mil lines and spaces. For example, technology is trending toward about 2-mil (or less) lines and spaces with staggered routing, and BT Laminate can accommodate these smaller lines and spaces. Thus, the number of I/O channels per MCM 105 can increase while reducing its corresponding footprint. In addition, reduction of parasitics can be attained through minimizing the distances between chips and eliminating the use of lead wires and solder bonds. However, the invention is not so limited. For example, other materials that exhibit similar attributes including high speed, compact, high reliability, low water absorption, high glass transition temperature, good thermal expansion coefficient match, and fine surface finishes can be employed. As an example, substrates such as FR-4 and polyimide (e.g., organic) can be utilized.

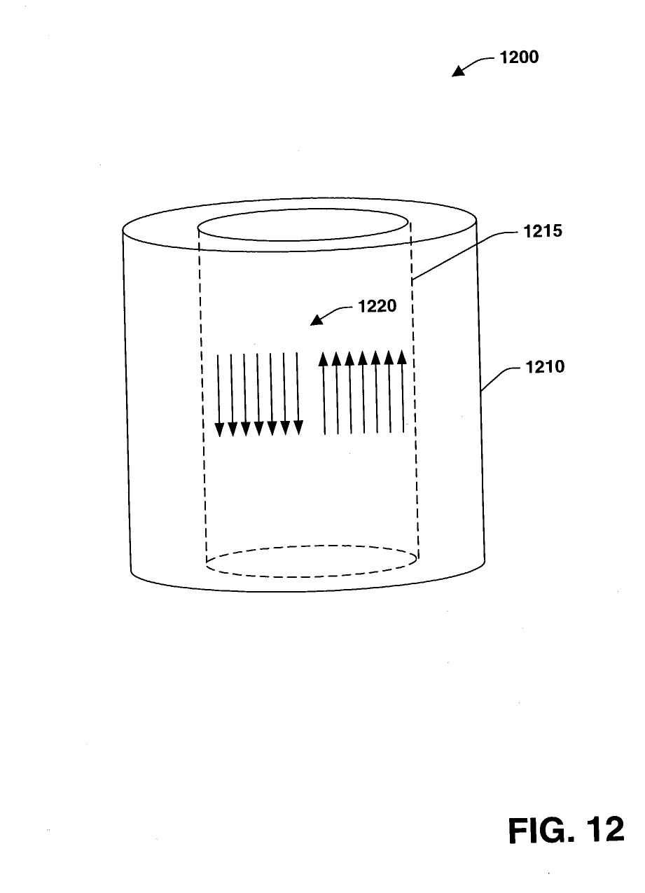

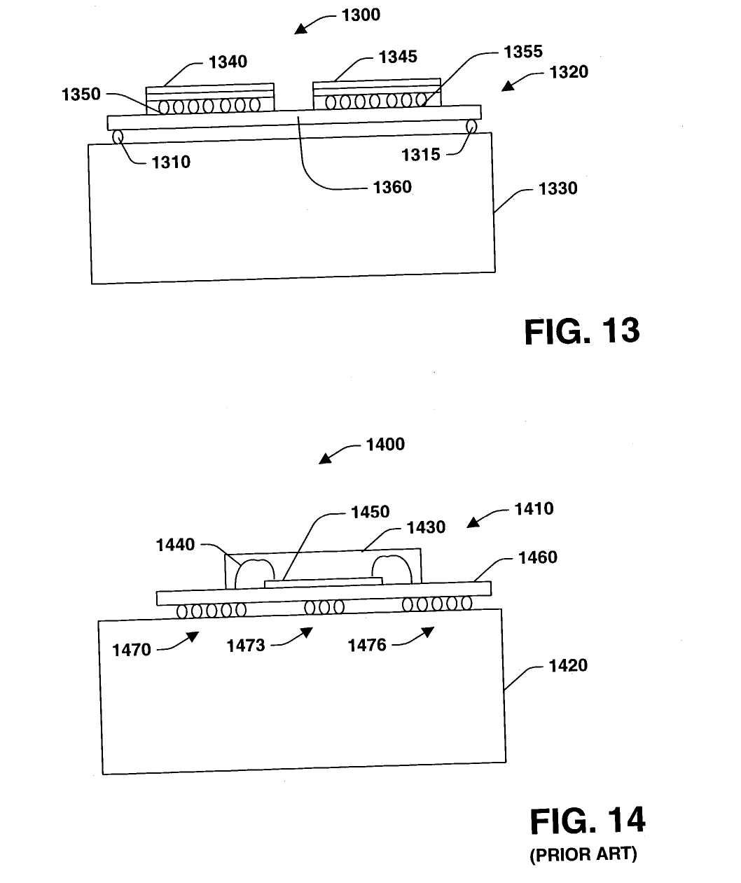

In one aspect of the present invention, the MCM 105 is an electronic package structure consisting of two or more “bare,” or unpackaged integrated circuits, or flip chips, interconnected on a common substrate (See FIGS. 13 and 14). The interconnects are usually multiple layers, separated by insulating material, and interconnected by conductive vias. A driving force behind MCMs 105 is the need to miniaturize and improve the performance of the conventional printed circuit board. MCMs offer better performance density per unit cost than conventional single-chip packages on printed circuit boards. As the need to improve performance as technology advances, the need to reduce wiring delay by mitigating individually packaged chips is evident. Signal delay is minimized in MCMs 105 due to a reduction in total length of the interconnect which, in turn, reduces parasitic circuit elements.

The MCM 105 interfaces with a main board component 120 (e.g., satellite controller) through an interconnect component 115 that facilitates high speed signal processing and mitigates wired connection schemes. Generally, many industries apply interfaces via surface mount or hard-wired technologies. However, these electrical interconnections typically do not scale with technology, wherein they usually need to be re-designed to keep up with state of the art devices. Thus, regularly it is the interconnection medium rather than the devices that act as a signal processing bottleneck. For example, electrical interconnections designed for 500 MHz probably will not work at 600 MHz because of inductance, crosstalk, and wave reflection phenomena. In addition, electrical connections are susceptible to loss at high frequencies, generation of undesired emissions, electromagnetic interference, etc. Furthermore, electrical connections should be planar or straight to minimize signal distortion. Accordingly, advances in technology force electrical paths to be re-designed or abandoned. For example, the trend in telecommunications has been to move away from electrical lines for long-distance traffic.

In one aspect, the present invention employs optical interconnects in the interconnect component 115. Optical interconnects provide dense interconnects at the chip level, facilitate lower power dissipation, smaller latency, and smaller physical size, provide the ability to integrate with mainstream silicon electronics in large numbers, while promoting transparency to electrical parasitics, and scalability. Thus, an optical system designed for 500 MHz can continue to work up to 500 GHz or more because the frequency of modulation has essentially no effect on the propagation of light signals.

In another aspect of the present invention, the main board component 120 receives signals from the interface components 115, which can include a plurality of signal processing components (not shown) and/or MCMs 105. The main board component 120 facilitates further signal processing of signals received from the MCM 105 and associated interconnect components 115, coordinates the transfer/processing of data, and facilitates other operations (e.g., satellite communications). In other aspects in accordance with the invention, a plurality of main board components 120 may interact to complete one or more tasks.

The main board component 120 may further include an applications component 125 and an instructions component 130, wherein the applications component 125 stores one or more applications. As an example, the system 100 may be part of a multispectral imaging system. The applications component 125 may include an application for scanning the surface of the earth employing multispectral scanning techniques. In addition, multiprocessing may be utilized to run serially or concurrently. For example, two or more scanning applications may run concurrently employing various wavelengths (e.g., infrared and ultraviolet).

The instructions component 130 may include lower level board instructions such as boot-initialization routines and associated drivers for interfacing with a systems input component 135 and systems output component 140. Additionally, the instructions component 130 may facilitate launching of the applications 125 at pre-determined times and/or on user demand, for example.

The systems input component 135 and systems output component 140, which can include multiple components, provide a manner for the main board component 120 to communicate outside of the system 100, wherein the input component 135 is employed to receive information or data of various types. This can include receiving request, commands and/or sampled data, for example. The output component 140 can be utilized to transmit information or data outside the system 100 (e.g., communicate with earth from space). This can include responding with error messages, queries, sampled data, energy emissions and/or manipulated data, for example.

As an illustration, the main board component 120 may execute instructions from instruction component 130, which launches a multispectral scanning application from the applications component 125. The output component 140 is then engaged to transmit radiation with a particular wavelength, whereby the input component 135 receives reflected radiation and conveys the data to the main board component 120. The main board component 120 then coordinates parsing the data to the MCM 105 via the interconnect component 115, and/or to a data storage component 145 (e.g., direct memory access (DMA)).

After data is operated on by the MCM 105, it can be returned optically via the interconnect component 115 to the main board component 120, which can store the manipulated data in the data storage component 145 and/or transmit it through the systems output component 140 to a remote location. Data stored in the data storage component 145 can also be operated on by the MCM 105.

In another example, a request to change the scanning spectrum and imaging resolution is received by the main board component 120 via the systems input component 135. The main board component 120 can then adjust frequency parameters to the systems output component 140. In addition, the main board component 120 can adapt the data pipeline to accommodate the increased data flow. This may entail increasing or instantiating a buffer in the data storage component 145 for temporary storage, utilizing more daughter cards and/or changing processing algorithms.

It can be appreciated that the above two examples were depicted to explain various aspect of the invention and do not limit it. For example, the system 100 may include more or less components, mechanisms and devices, acting in capacities known in the art but not included in the example. For example, the MCM 105 may interface with its own memory (e.g., local or remote) for instructions, data storage and data buffering. In addition, data may be operated on serially by different signal processing components and/or the main board component 120.

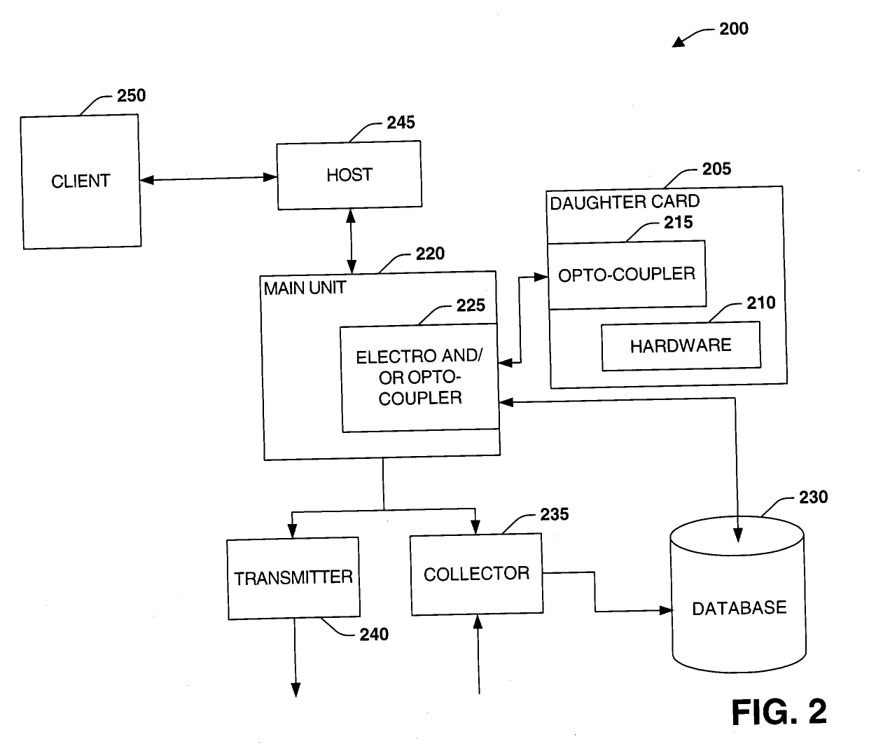

Referring now to FIG. 2, an exemplary example of an aerospace signal processing system 200 is illustrated in accordance with the present invention. The system 200 incorporates a daughter card 205 and a main unit 220, and optionally a database component 230, a collector component 235, a transmitter component 240, a host component 245 and a client component 250.

In one aspect of the present invention, BT Laminate may be employed to construct the daughter card 205 as noted above, however, other materials may be employed that similarly facilitate higher density circuit routings and/or couplings. BT Laminate is desirable because it accommodates higher I/O MCMs in a smaller space through tighter lines and spaces.

The daughter card 205 further includes a hardware component 210 (can include software elements) that can encompass one or more of the following: application specific integrated circuits(ASICs), memory modules, digital signal processors (DSPs), lasers, laser drivers, optics, firmware, integrated circuits (ICs), multichip modules (MCMs), etc. As noted supra, plastic encapsulated chips can be employed to reduce weight and cost. In one aspect of the subject invention, plastic-encapsulated microcircuits (PEMs) components are utilized. PEMs, often called plastic packages, embrace an integrated circuit chip attached to a leadframe, interconnected to input-output leads, and molded in a plastic that is in direct contact with the chip, leadframe, and interconnects.

PEMs are employed in commercial and telecommunications electronics and have a large manufacturing base. With major advantages in cost, size, weight, performance, and availability, plastic packages have attracted the market share of worldwide microcircuit sales, including gaining acceptance for use in government and military applications. In the early 1990s, the semiconductor industry dispelled the notion that hermetic packages (e.g., ceramic) were superior in reliability to plastic packages. Today, high-quality, high-reliability, high-performance, and low-cost plastic-encapsulated microcircuits are common.

The daughter card 205 also includes an opto-coupler component 215. The opto-coupler 215 provides a wire-free interconnect with the main component 220. This mitigates the need for solder mounting, and unsoldering in order to repair/replace components. It also mitigates high lead inductance that severely degrades I/O performance at higher frequencies, for example at 500 MHz and beyond. Thus, frequency modulation scaling can be achieved without re-design, unlike electrical pathways which are not as transparent to frequency changes and generally do not scale with technology.

It can be appreciated that more than one daughter card 205 may exist, wherein respective daughter cards may perform a particular task. For example, data binning may be performed on one card, another card may be implement a geometrical correction on the data and yet another card may convolve the data with a smoothing or sharpening kernel. Several daughter cards 205 may perform the same or similar tasks. For example, several daughter cards 205 may reside at the end of a data pipeline. This affords the opportunity for parallel processing. In addition, serial processing can take place as a card reaches its capacity, operations on the data can commence while incoming data accumulates in the next card. The above examples are provided for explanatory purposes and are not intended to be all-inclusive.

The main unit 220 further includes an electro and/or opto coupler 225. The electro and/or opto coupler 225 interfaces with the opto coupler 215 of the daughter card 205. The coupling can be bidirectional for transmission of data between the main unit 220 and daughter card 205. Transmission from the daughter card 205 can include maintaining optical data on the main unit 220 by employing optical waveguides on the main unit, for example through embedded polymeric optical waveguides. In addition, optical signals may be converted back to electrical signals through opto-to-electrical conversion, for example for use with a PCB motherboard. Data transmission to the daughter card 205 may also include transmitting an optical signal or converting an electrical signal to an optical signal and then re-transmitting it. In addition, it can appreciated that a multiplexer may exist to combine signals for transmission over a high speed optical link and then separate the signals once received. In addition, two or more unidirectional optical links may be employed for data transmission.

The main unit 220 facilitates the storage and retrieval of data in the database component 230. Data received by a collector component 235 can also be stored in database component 230. In addition, data can be conveyed to the daughter card 205 for processing through the database component 230. Stored data can also be moved from the database component 230 to the daughter card 205 though the main component 220. Furthermore, data processed by the daughter card 205 can be stored in database component 230.

The main component 220 controls/interacts with the collector component 235 and the transmitter component 240. As noted above, the collector component 235 receives data, which can be either stored in the database component 230 or placed in the processing pipeline, whereas the transmitter component 240 dispatches signals. An example application is multi-spectral imaging, where the transmitter transmits radiation within a spectral range. Reflected radiation characteristic of the structure in the transmitted radiation path is received by the collector component 235.

The host component 245 typically fulfills the client requests from the client component 250 by performing requested tasks. Generally, the host component 245 receives requests from the client component 250, executes database retrieval and updates, manages data integrity and dispatches responses to requests. It can be appreciated that the host component 245 may be embedded within the main component 220 or reside on another component on the same network or backplane, or through another transmission link and/or protocol, for example.

The host component 245 can further include at least one server (not shown). Servers in accordance with the present invention include disk, file and database servers. With a database server, for example, the client component 250 passes requests over a network (e.g. satellite) to the host component 245. The request can be, for example, a Structured Query Language (SQL) request. Requests may involve raw and/or processed data stored in the database component 230 wherein, the database component may be an SQL or other type database (e.g., XML database).

The client component 250, which may include a graphical user interface (GUI), initiates a message to the host component 245, requesting that the host perform a task or service. Usually, the client component 250 manages the user-interface portion of an application, validates data entered by the user (or provided by a system) and dispatches requests to the host component 245. The client-component 250 is generally at the front end of an application that the user sees and interacts with, and it interfaces the user and the rest of the application.

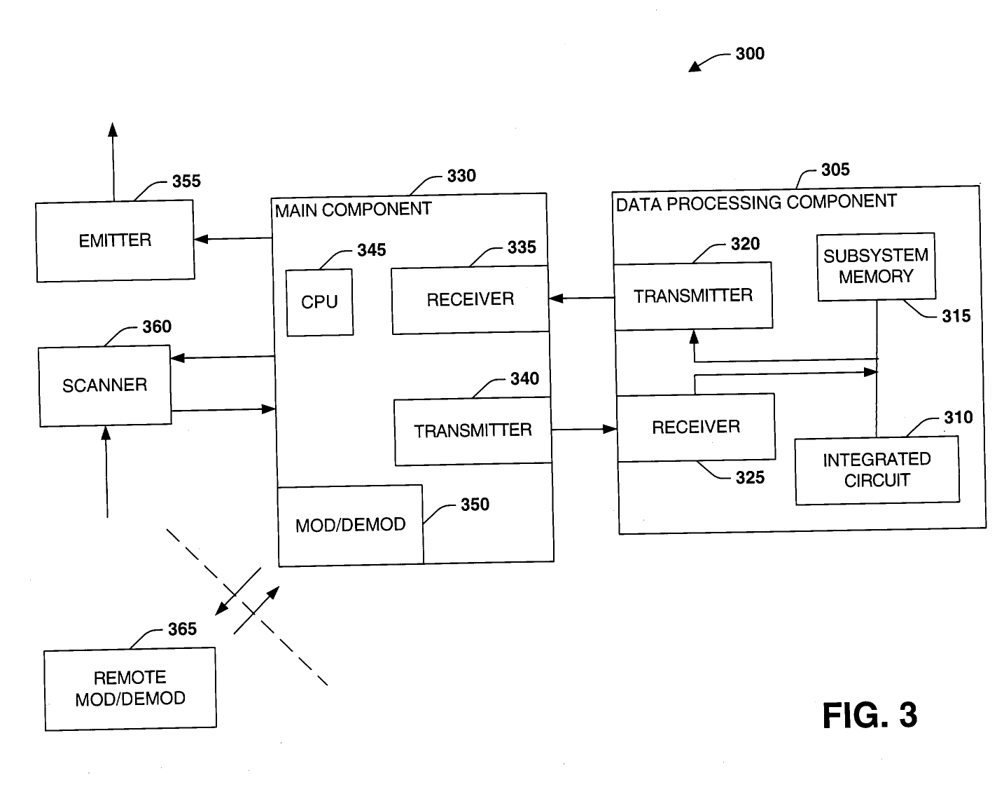

Turning to FIG. 3, an exemplary satellite communications data processing system 300 is illustrated in accordance with an aspect of the subject invention. The satellite communications data processing 300 includes a data processing component 305 and a main component 330, and optionally an emitter component 355 and a scanner component 360, and remotely interfaces with a remote mod/demod component 365.

The data processing component 305 further includes an integrated circuits (IC) component 310, a subsystem memory component 315, a transmitter component 320 and a receiver component 325. In one aspect of the invention, the data processing component 305 is substantially smaller in size and weight having less cost than conventional components.

The IC component 310 can include a plurality of integrated circuits which contain electronic circuitry encompassing individual circuit elements, for example transistors, diodes, resistors, capacitors, inductors, and other active and passive semiconductor devices, formed on a chip of semiconducting material and mounted on a substrate material. The IC component 310, depending on the number of integrated circuits and the materials used, can also encompass MCMs and PEMs.

In accordance with one aspect of the present invention, the IC component 310 and associated integrated circuits are fabricated with low cost plastic encapsulation and can be employed as flip-chips. Furthermore, in order to increase the number of I/O and reduce chip footprint, the integrated circuits are mounted on laminate data processing components 305, which affords denser I/O per unit area.

The subsystem memory component 315 provides on-board memory for micro code, drivers and quick access to temporary storage, for example. It is connected to the IC component 310, the transmitter 320 and the receiver component 325 through a data bus. This enables the IC component 310 to store data from the receiver component 325, read from and write to memory when needed, and return data from the subsystem memory component 315.

The subsystem memory 315 may include volatile and nonvolatile memory. Volatile memory includes random access memory (RAM), which can act as external cache memory. RAM is available in many forms such as synchronous RAM (SRAM), dynamic RAM (DRAM), synchronous DRAM (SDRAM), double data rate SDRAM (DDR SDRAM), enhanced SDRAM (ESDRAM), Synchlink DRAM (SLDRAM), and direct Rambus RAM (DRRAM). Nonvolatile memory can be include read only memory (ROM), programmable ROM (PROM), electrically programmable ROM (EPROM), electrically erasable programmable ROM (EEPROM), or flash memory.

The transmitter component 320 and the receiver component 325 provide an optical system to transfer data between the data processing component 305 and the main component 330. Optical transmission and reception provides non-wired data transmission, eliminating electrical connections averts degradation caused by parasitics and wave reflections and limitations to scalability. For example, lead inductance and capacitance can degrade performance for transmissions in the megahertz frequency range.

Optical transmissions are generally not susceptible to these electrical connection deficiencies. In addition, transmission rates can increase without the need for re-designing the transmission medium, as with electrical transmission paths. As shown, optical coupling can be through separate channels. Various pathways, up-link and/or down-link, may multiplex signals from several signals into one high speed signal and then back into several signals once received. It can be appreciated that the optical link may be bidirectional and encompass both up and down links.

The main component 330 further includes a transmitter component 340, a receiver component 335, a central processing unit (CPU) 345 and a mod/demod 350. The transmitter component 340 and the receiver component 335 complement the receiver component 325 and the transmitter component 320 of the data processing component 305. Again, they provide an optical path of communication between the data processing component 305 and the main component 330. This facilitates scalable high-speed communication that is not as susceptible to electrical issues, for example cross-talk or chatter between I/O channels.

In addition, the main component 330 may employ optical waveguides through embedded polymeric optical waveguides for optical on board signal routing. However, an optical signal to electrical signal converter may exist to convert the optical signal to an electrical signal, if desired.

The CPU 345 facilitates communication between the data processing component 305 and the main component 330. In addition, it controls the emitter component 355, the scanner component 360 and the modulator component 350.

The emitter component 355 can emit energy within a wavelength range, for example. The CPU 345 activates and disables the emitter component 355, and adjusts one or more emission parameters. The scanner component 360 enables reception of reflected energy and can be activated and disabled by the CPU 345. The CPU 345 also facilitates the storage and processing of the data as can be appreciated.

The mod/demod component 350 of the main component 330 and the remote mod/demod component 365 can be employed in concert. In one aspect, the mod/demod component 350 can translate signals to a carrier frequency for transmission to the remote mod/demod component 365. This can be performed to overcome inefficiencies related to transmitting the signal and for security through encryption. Modulation takes place by varying some characteristic of the high frequency carrier in accordance to the signal. Generally, this is achieved by varying frequency (frequency modulation), amplitude (amplitude modulation) or phase (phase modulation) of the carrier. The remote mod/demod component 365, which generally is located at a remote location, separates the desired signal from the carrier frequency and can also translate signals to a carrier frequency for transmission to the mod/demod component 350. Similar modulation techniques are employed. The mod/demod component 350, upon receiving the modulated signal, can separate the desired signal from the carrier frequency. The signals communicated between the mod/demod components 350, 365 can be messages, requests, instructions, parameter changes, raw and/or processed data, for example.

Modulation techniques can include analog and/or digital techniques. Generally, analog modulation in satellite communication is frequency modulated, and digital modulation in satellite communication is amplitude, frequency and phase modulated. In the digital domain, amplitude, frequency and phase modulation are referred to as Amplitude shift keying (ASK), Frequency shift keying (FSK) and Phase shift keying (PSK). Other techniques used in digital modulation are all called Quadrature Amplitude Modulation (QAM), these have been designed for digital communication to optimize data transfer. In satellite communication, PSK is the technique most commonly used. FSK is also used in certain applications where receiver simplicity is essential. ASK is rarely used in earth-space communications, this is again because Amplitude modulation is more susceptible to noise.

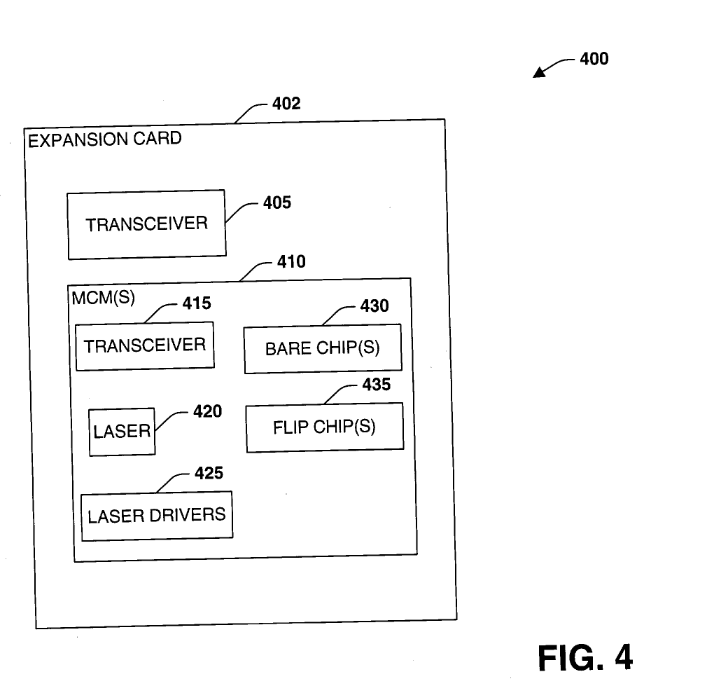

FIG. 4 illustrates an exemplary expansion board 400 in accordance with an aspect of the invention. The expansion board 400 includes an expansion card 402, a transceiver component 405 and an MCM(s) component 410. It can be appreciated that the components and component layout illustrated do not limit the expansion board 400. The component's size and relative positions to each other are pictorial representations and are not indicative of actual physical layout. The expansion card 402 can be constructed of BT Laminate or other materials possessing similar characteristics such as the ability to accommodate high-density lines and spaces. The transceiver component 405 provides optical transmission and reception to and from the expansion card 402. Optical transmission and reception mitigates electrical interconnections, which can contaminate the signal through inherencies such as wave reflections, cross-talk, voltage isolation, impedance matching and pin inductance, for example.

The transceiver component 405 may provide a plurality of unidirectional and/or bidirectional channels. In addition, the optical signals may be duplexed or multiplex to form a signal for high speed communication. It can be appreciated that the receiving end of a signal transmitted by the transceiver 405 may convert the optical signal back to an electrical signal. However, the receiving end may contain an optical bus and have the capability to route optical signals.

The MCM(s) component 410 further includes a transceiver component 415, a laser component 420, a laser driver component 425, a bare chip(s) component 430 and a flip chip(s) component 435. The transceiver component 415 on the MCM(s) component 410 transmits/receives data between chips 430, 435, other MCMs (not shown) and/or to the expansion board 402. Similar to transceiver component 405, the transceiver component 415 can be optical in nature. Again, optical interfaces can be employed to overcome constraints associated with electrical interfaces such as I/O pin counts and clock rates.

The laser component 420 provides a mechanism for creating the optical signal. In one exemplary example, the laser can be transmitted through a diffractive prism onto a second prism where it is reflected and propagated horizontally to the expansion board 400, or reflected again and propagated vertically to the expansion board 400. This allows optical interfaces to be positioned horizontally and/or vertically (or other angles) to the expansion board 400. The laser components driver 425 provides power capabilities for the laser component 420.

The bare chip(s) component 430 includes bare or unpackaged integrated circuits. The bare chip die can be attached to an unprocessed support substrate. Fabrication can occur on top of the die, resulting in modules with the ICs buried beneath the interconnect and associated ground and power planes (not shown), and with no bond wires. Bare chips can also be mounted on a previously patterned substrate. Interconnections between chip circuitry and on chip pads are commonly achieved through wire connections. Interconnections between the chip and substrate are can also be through wire connections. The flip chip(s) component 435 includes unpackaged ICs that can be mounted face down for direct contact with the substrate.

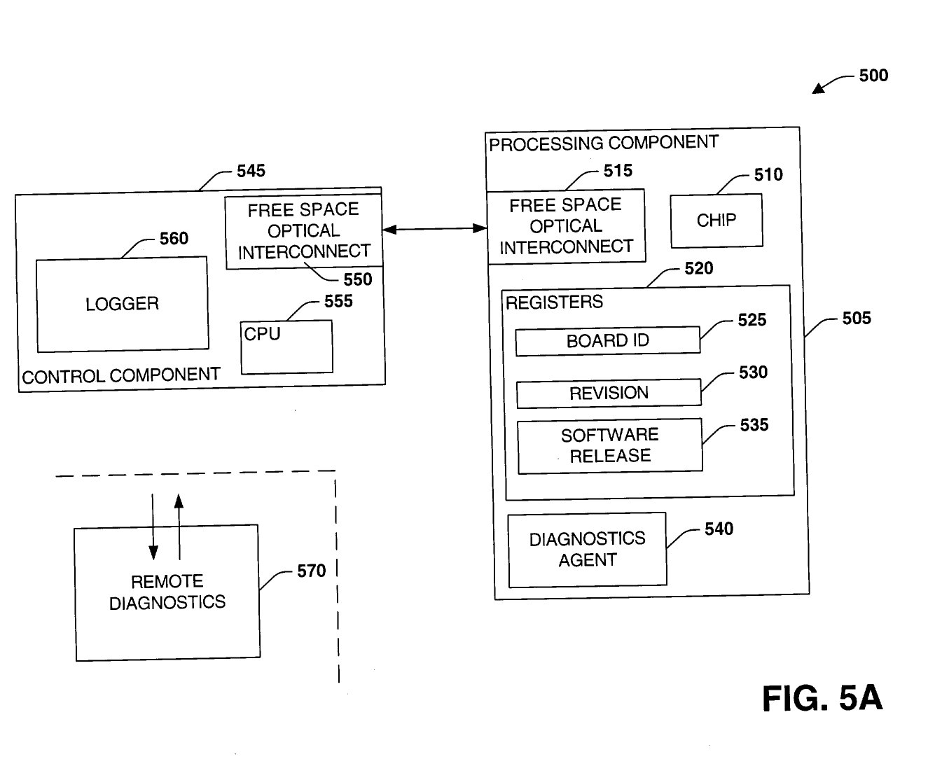

FIG. 5A illustrates a system 500 with board level diagnostics in accordance with an aspect of the present invention. The system 500 includes at least one processing component 505, a diagnostics component 540, a control component 545 and, optionally, a remote diagnostics component 570.

The control component 545 further includes a free space optical interconnect (FSOI) component 550, and optionally a CPU component 555 and a logger component 560. Upon applying power to the system 500, the CPU component 555 transmits a reset signal to the processing component 505. The reset signal can be transferred to the processing component 505 over the FSOI component 550. The FSOI component 550 establishes an optical interface between the control component 545 and the processing component 505, whereby an optical interface relieves the need to connect the control component 545 and the processing components 505 through wires and/or solder joints.

The optical interconnect provides other benefits such as not being vulnerable to contaminants electrical connections introduce into the system 500. Inherent to electrical connections are, for example, resistive capacitive and inductive parasitics that can degrade system performance. In addition, the FSOI component 550 is generally transparent to data rate increases. For example, increasing rates from 500 MHz to 5 GHz will generally be transparent to the FSOI components 550 and the FSOI components 515. This is contrary to electrical interconnects that generally have to be re-designed as data rates move with technological advances.

The logger component 560 logs system activities, including processing component 500 board level diagnostics. It can also record communications between the control component 545 and the remote diagnostics component 570, wherein a log of activities can be utilized to maintain permanent records or queried for requested reports. In addition, the log may be beneficial for trouble shooting system and/or module errors.

The CPU component 555 facilitates transferring information between the control component 545 and the processing component 505 and between the control component 545 and the remote diagnostics component 570. In addition, it coordinates the processing of information in accordance with the logger component 560.

The processing component 505 further includes a chip component 510 and a FSOI component 515, and optionally, a registers component 520 and a diagnostic component 540. The registers component 520 further includes a board identification (“board id”) component 525, a revision component 530 and a software release component 535.

The chip component 510 may include inexpensive, radiation hardened, plastic encapsulated integrated circuits (p-ICs) and/or plastic multichip modules (p-MCMs) whereby associated chips can be mounted face up and/or face down. Bare chip dies can be placed face up and fabricated into the substrate for wireless connection between the chip and substrate, for example, and can also achieve wireless connections by placing them face down, or in flip chip configuration, on the substrate. Bare chips can also be mounted on a previously patterned substrate. Packaged chips may also be employed.

The FSOI component 515 complements the FSOI component 550 on the control component 545. It provides a wireless information pathway between the control component 545 and the processing components 505. It can also be utilized on the processing component 505 for on-board optical communication between chips and chip modules. Again, it provides benefits like data rate scalability and resistance to noise stemming from electrical lead wires and bonds.

The FSOI component 515 typically receives a reset signal from the control component 545. The diagnostic component 540 proceeds with a board level boot. During booting, the diagnostic component 540 facilitates board integrity, which can include testing the chip component 510, the FSOI component 515 and memory. If no errors are determined, then the diagnostic component 540 can return a message to the control component 545 over the FSOI component 515 indicating that it has initialized without errors. If errors are discovered, then the diagnostic component 540 can dump the contents of the registers component 520 and the results of the diagnostic testing to the logger component 560 of the control component 545.

The contents of the registers component 520 provide board specific information. For example, the board id component 525 contains information identifying the board. The revision component 530 reveals the hardware revision. Hardware revisions may include adding and/or deleting components, or re-routing of components. The software release component 535 identifies the firmware.

It is noted that the system 500 may be on an aircraft or satellite where it is not easily accessible to humans. If one of the processing components 505 is defective and the system 500 is not accessible, then the registers component and diagnostic information can be remotely retrieved from the logger component 560 in order to troubleshoot the system 500. The remote diagnostics component 570 may send a request for the contents of the logger 560, or it may request specific information from the logger. For example, it may inquire board id from the processing components residing on system 500, or it may request information specific to a particular processing component.

It can be appreciated that the diagnostics functionality can extend beyond boot diagnostics. For example, diagnostics can be utilized to upload new, specific or beta software and firmware, and patches. The remote diagnostics component 570 may send the software/firmware along with instructions that are readable and executable by the CPU component 555. The CPU 555 can then facilitate the loading and testing of the software to the processing component 505.

Furthermore, diagnostics may be used to automate processes like setting up newly installed processing components (e.g., plug and play) and removing information pertaining to previously set up processing components. For example, when the processing component 505 is connected, the CPU 555 may poll processing components for register information. Upon receiving register information for a processing component not already recorded, the CPU component 555 can commence a processing component set up routine.

FIG. 5B illustrates a board level diagnostics methodology 580 in accordance with an aspect of the present invention. While, for purposes of simplicity of explanation, the methodologies may be shown and described as a series of acts, it is to be understood and appreciated that the present invention is not limited by the order of acts, as some acts may, in accordance with the present invention, occur in different orders and/or concurrently with other acts from that shown and described herein. For example, those skilled in the art will understand and appreciate that a methodology could alternatively be represented as a series of interrelated states or events, such as in a state diagram. Moreover, not all illustrated acts may be required to implement a methodology in accordance with the present invention.

Proceeding to reference numeral 582, power is applied to an expansion board such as the processing component 500 described above. The power can be derived from a motherboard interfaced with the expansion board and/or a test fixture employed to test expansion boards, an internal power supply (e.g., a battery), a backup power supply (e.g., a UPS) and the like.

Upon receiving power, the expansion board boots, and code can be executed which launches a diagnostics utility, engine and/or routine, for example. At 584, the diagnostics can reset and interact with at least a board level component, including re-starting the diagnostics code if errors are detected with the prior launch.

At 586, diagnostic (e.g., proprietary and off-the-shelf) are performed, wherein the results can be selectively logged internally and/or externally to the expansion board. For example substantially all the results can be logged or a subset like a diagnostics associated with a failed test and/or a test associated with an error prone component. In addition, the diagnostics can be performed serially or concurrently with one or more components.

Analysis of a diagnostic is performed at 588. Analysis can be performed on-the-fly (e.g., as the result is obtained) and followed by a subsequent action or step, if desired. In addition, the analysis can be performed at a later time. For example, when several results facilitate in determining the state (e.g., acceptable and not acceptable), analysis can be performed after the results are acquired and/or as a result is acquired wherein the state is determine based on more than one result.

If diagnostics deem a board acceptable, then at 590 a transmit ready signal is made available (e.g., the signal can be pushed, pulled and broadcast) to devices, including itself, with the capability and clearance to receive the signal. In an aspect of the invention, diagnostics can deem a board acceptable although at least one error and/or corrupt component exists. For example, it can be determined that the fault detected is not significant enough (e.g., low priority and/or not related to the current processing job) to halt processing. In another aspect, any failed test can raise an interrupt or flag, for example, and halt board processing to mitigate the propagation of corrupt data.

If diagnostics deem the board unacceptable, then at 592 the content of the board registers can be dumped to a logger (e.g., local and remote). Register information can provide board information such as an identification number, a revision identifier and/or a software release designator. Additionally, the diagnostics performed as well as associated analysis can be tagged with the register information.

At 594, a board deemed acceptable enters an idle state in which the board can be become available to for employment. A board deemed unacceptable can enter an idle state, wherein the board can be isolated from employment until issues are resolved and/or the board is replaced.

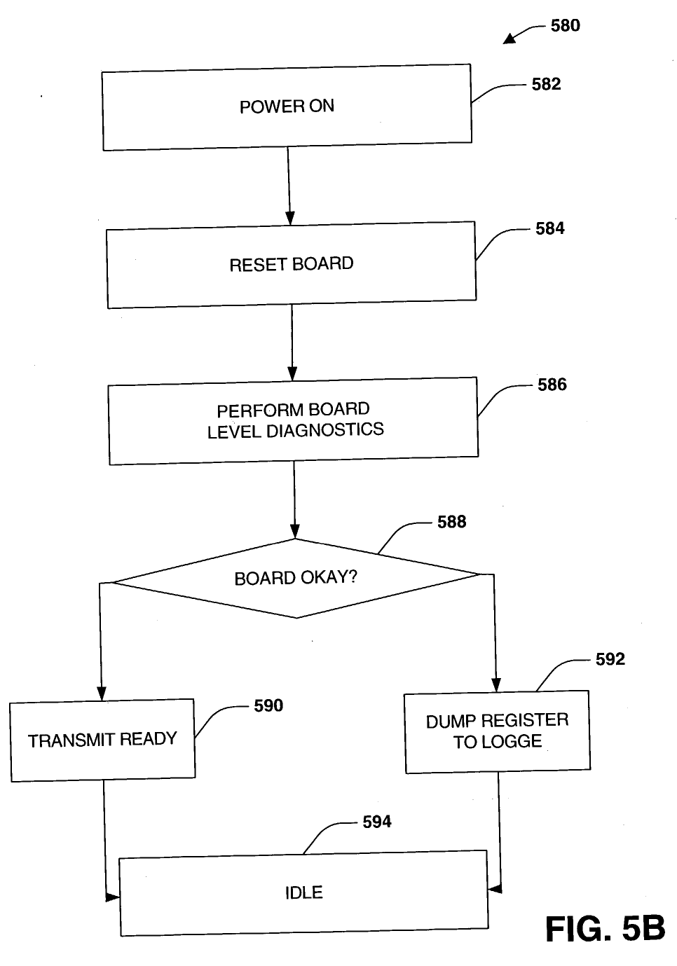

Fig.6 illustrates a system 600 that includes several processing cards residing on an optical backplane in accordance with an aspect of the present invention. System 600 includes a computing component 610, one or more cards components 620-650, and an optical backplane 660. The cards components 620-650 are constructed of suitable materials for high I/O chip module population. For example, the material may include BT Laminate, which can accommodate 2-mil lines and spaces. The card component 620 further includes a plurality of integrated circuits (ICs) (not shown) and/or a plurality of multichip modules (MCMs) (not shown). The ICs and MCMs contain electrical circuitry to perform application specific tasks.

The card components 620-650 further include an optical interface (not shown). The optical interface can be employed for chip-to-chip, chip-to-module, module-to-chip, module-to-module, and the card component-to-computing system 610 interconnects. Optical interconnects facilitate dense interconnects, small latency, small size and the ability to integrate with mainstream silicon electronics.

Data is transferred between the card components 620-650 and the computing system 610 over the optical backplane 660. In addition, data can be transferred between cards over the optical backplane 660. The computing system 610 may include embedded optical waveguides. Optical waveguides enable the optical signals received from the card components 620-650 to be routed optically within the computing component 610 rather than having to convert them to electrical signal before routing. Likewise, electrical signals within the computing system 610 do not have to be converted to optical signals before conveying them over the optical backplane 660 to the card component 620-650. Optical waveguides, in one example, thus can relieve the conversion process.

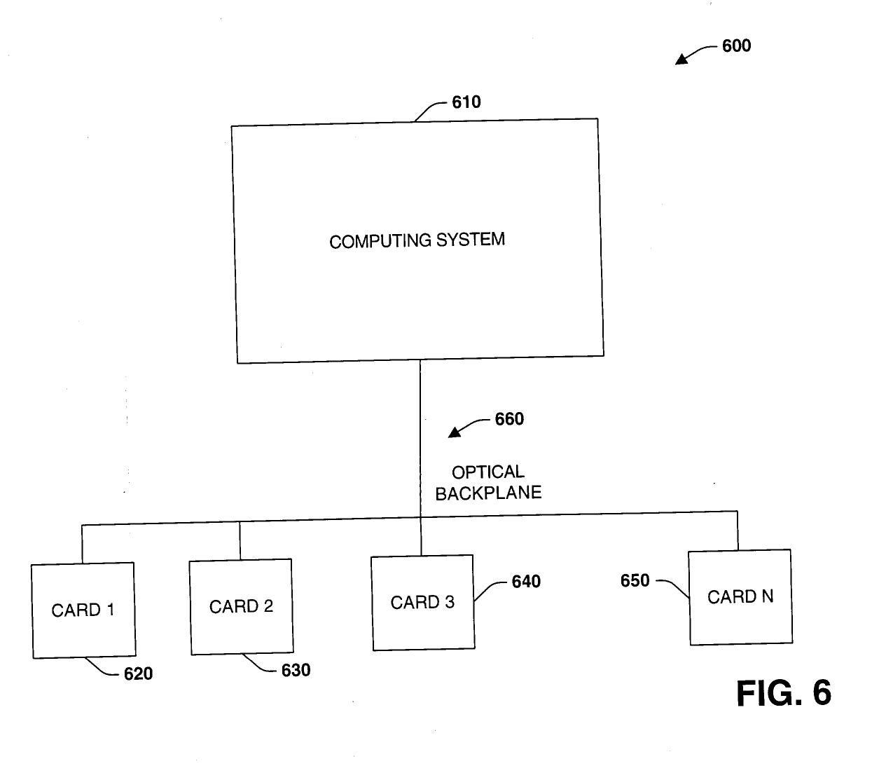

FIG. 7-11 illustrate exemplary daughter cards, daughter card to mother board connections and optical interconnects in accordance with the present invention. Component are presented as simple structures and should not be construed as actual components or limiting the actual components or layout.

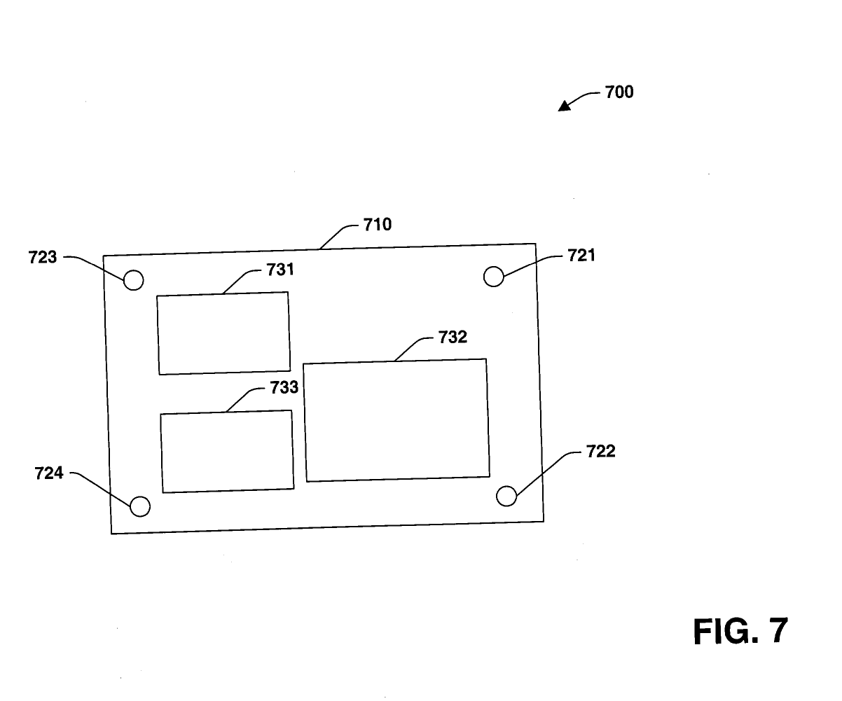

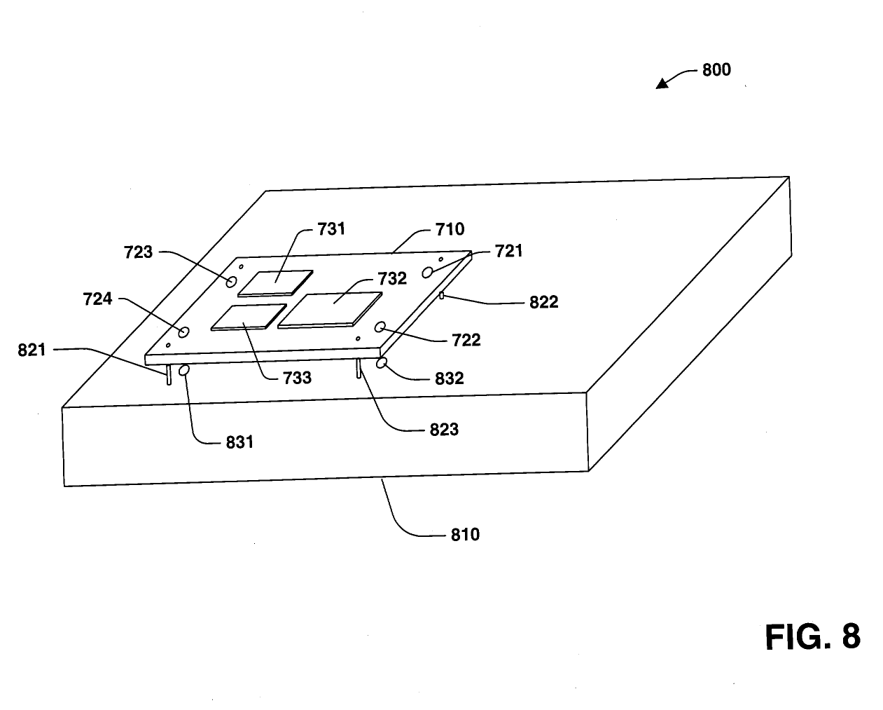

Beginning with FIG. 7, a system 700 illustrates a top view of an exemplary plastic multi-chip module (PMCM) Daughter Board 710 in accordance with an aspect of the subject invention. The PMCM Daughter Board 710 is a double sided board (e.g., double sided copper clad circuit board), however a single sided board can be employed. The double sided nature of the PMCM Daughter Board 710 provides at least two surfaces in which the aforementioned components can be mounted. For example, components can be mounted on a side or on both sides of the PMCM Daughter Board 710 concurrently. Operatively mounting components on opposing sides can reduce the distance between the operatively mounted components. For explanatory purposes, the top view of the PMCM Daughter Board 710 is described with FIGS. 7 and 8, and an opposing side is described with FIG. 9.

The top view of the PMCM Daughter Board 710 includes one or more Free Space Optical Interconnects 721, 722, 723, 724 and one or more Flip Chip Application Specific Integrated Circuits (ASICs) 731, 732, 733. The Free Space Optical Interconnects 721, 722, 723, 724 enable optical communication with another board, for example a motherboard or another expansion board. Optical communications provides a scalable high speed medium that is less vulnerable to electrical related contaminates. In addition, since the PMCM Daughter Board 710 does not have to be electrically connected to a motherboard, serviceability, for example board replacement, is improved since components do not have to be unsoldered.

The Flip Chip ASICs 731, 732, 733 are generally constructed with silicon and/or other semiconductor material. Generally, many industries employ more expensive ceramic packaged components. For example, a mezzanine board may include a plurality of multi chip modules (MCMs) that cost over $100,000 each. Using low priced plastic encapsulated ASICs may reduce cost to about $5,000 to $6,000 per module. Such ASICs can be constructed with a variety of electrical devices or components, for example semiconductors, operational amplifiers, resistors, transistors and optoelectronics, in order to obtain desired functionality.

Referring now to FIG. 8, a system 800 illustrating an exemplary perspective view of the PMCM Daughter Board 710 depicted in FIG. 7 and mounted to a motherboard 810. The system 800 includes at least one PMCM Daughter Board 710, a motherboard 810 and optionally a plurality of stand offs 821, 822, 823 or other connectors that allow boards to be easily installed and removed.

The motherboard 810 could be a conventional PCB or it could contain embedded optical fibers (e.g., optical bus) for on board signal routing. Without optical waveguides, signals may be routed as electrical signals. The electrical signals can be converted to optical signals prior to transmitting them over the optical bus, whereas signals arriving from the optical bus are converted back to electrical signals.

The PMCM Daughter Board 710 can be mounted to the motherboard 810 through a fastenable mechanism, for example the standoffs 821, 822, 823, in order to connect and remove boards when desired. It can be appreciated that other types of fasteners, for example connectors, expansion slots, mounting screws, sockets and right angle brackets and others can be employed.

Also shown on the motherboard 810 are a corresponding optical interconnects 831, 832 for optical transmission between the motherboard 810 and the PMCM Daughter Board 710.

FIG. 9 depicts a side view of the exemplary system 800. The system 800 includes the PMCM Daughter Board 710, the motherboard 810 and the plurality of stand offs 821, 823. The PMCM Daughter Board 710 is presented with the Flip Chip ASICs 732, 733 and the Free Space Optical Interconnects 722, 724 as described above, and further with an ASIC 825 and an electrical/electronical component such as a capacitor 827 (e.g., bypass and coupling). As previously described, the double sided nature of the PMCM Daughter Board 710 provides at least two surfaces in which the aforementioned components can be mounted. The PMCM Daughter Board 710 employs the ASIC 825 and the capacitor 827 on the opposing side of the PMCM Daughter Board 710. Operatively coupling components on opposing sides, for example the Flip Chip ASIC 733 and the capacitor 827, minimizes the electrical path between the Flip Chip ASIC 733 and the capacitor 736, thus reducing parasitics.

For explanatory purposes of the optical transmission, the Free Space Optical Interconnect 722 will be referred to as a receiver diode 722, and the Free Space Optical Interconnects 724 will be referred to as a transmitter diode 724. Furthermore, motherboard optical interconnects 831 will be referred to as receiver diode 831, and 832 will be referred to as transmitter diode 832. Data transfers from the transmitter diode 724 of the PMCM daughter card 710 can be directed to the reciver diode 831 of the motherboard 810. Similarly, data transfers from the transmitter diode 832 of the motherboard 810 can be directed to the receiver diode 722 of the PMCM daughter card 710. It is to be appreciated that a bidirectional channel may also be employed to transfer data. In addition, the optical signals may be multiplexed to form a high-speed channel for data transfer.

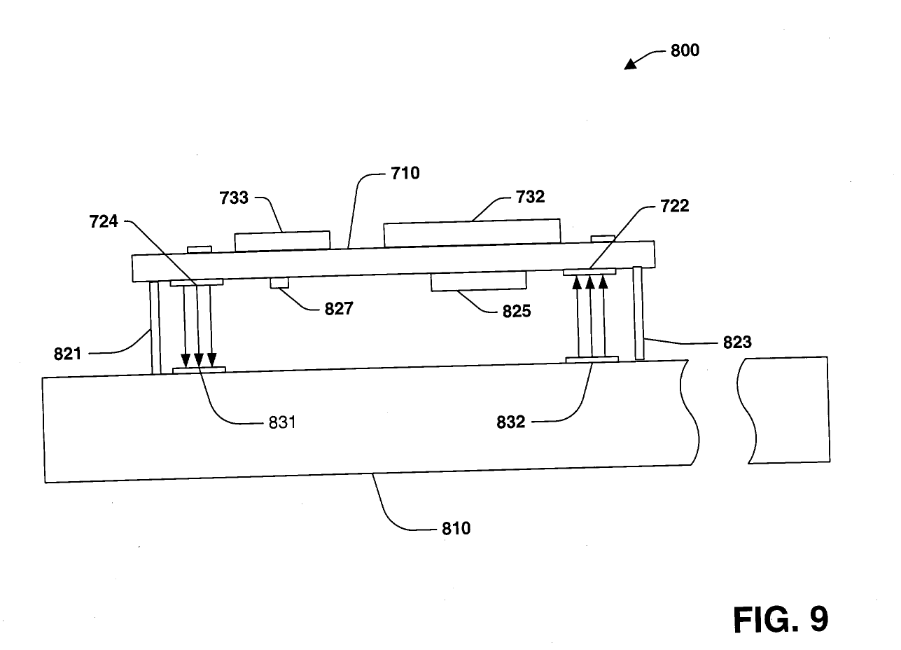

FIG. 10 illustrates an alternative method for mounting a PMCM daughter board to a motherboard 1050. One or more PMCM daughter boards 1010, 1020, 1030, 1040 can be connected perpendicularly (or other angle) to a motherboard 1050. For example, a right angle bracket may be employed to hold the cards in place. In another example a fastening screw or set screw may be utilized. For the perpendicular configuration, the optics from the PMCM daughter boards can propagate horizontally with the PMCM daughter boards to the motherboard 1050.

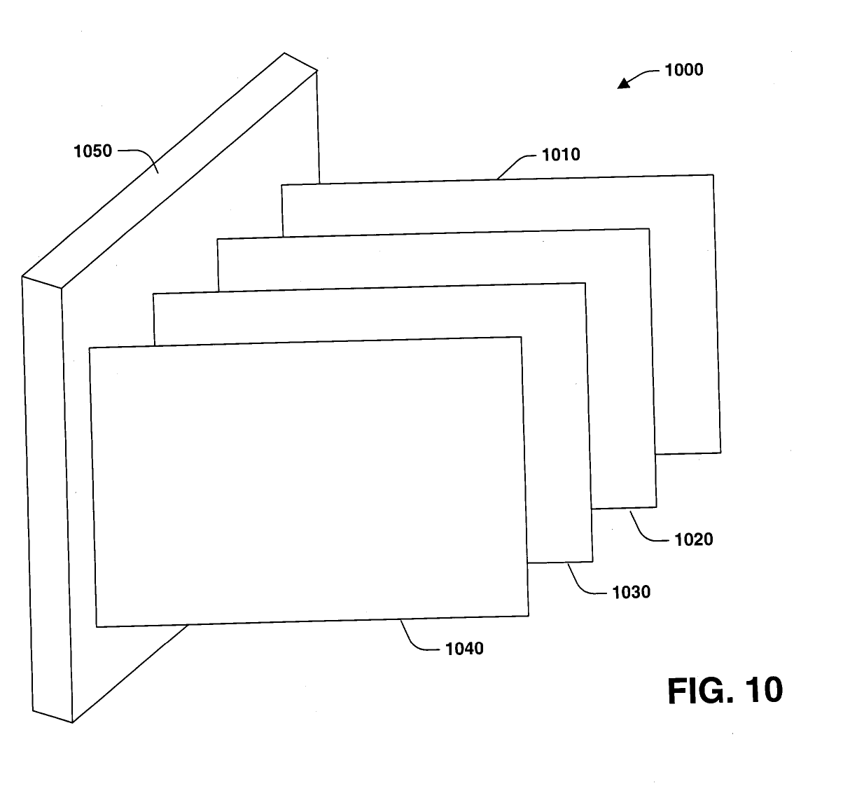

FIG. 11 depicts another method for mounting a least two daughter cards to a motherboard. The PMCM daughter boards 1110, 1120, 1130, 1140 are stack mounted to a motherboard 1140. Stack mounting of daughter boards can be accomplished utilizing any of the known techniques in the art. In the figure, an exemplary stack mounting scheme is illustrated. The stack mounting scheme entails employing an opto-mounting device 1151, 1152, 1153, 1154, 1155, 1156 which provides a physical connection between the daughter board 1130 and motherboard 1140, or between two daughter boards, for example daughter board 1120 and daughter board 1130, and the Free Space Optical Interconnect (FSOI) channels (not shown). In the illustration, the FSOI channels lay within the opto-mounting device 1151, 1152, 1153, 1154, 1155, 1156, however it can be appreciated that the support structure could be internal and the FSOI channels could surround the support structure.

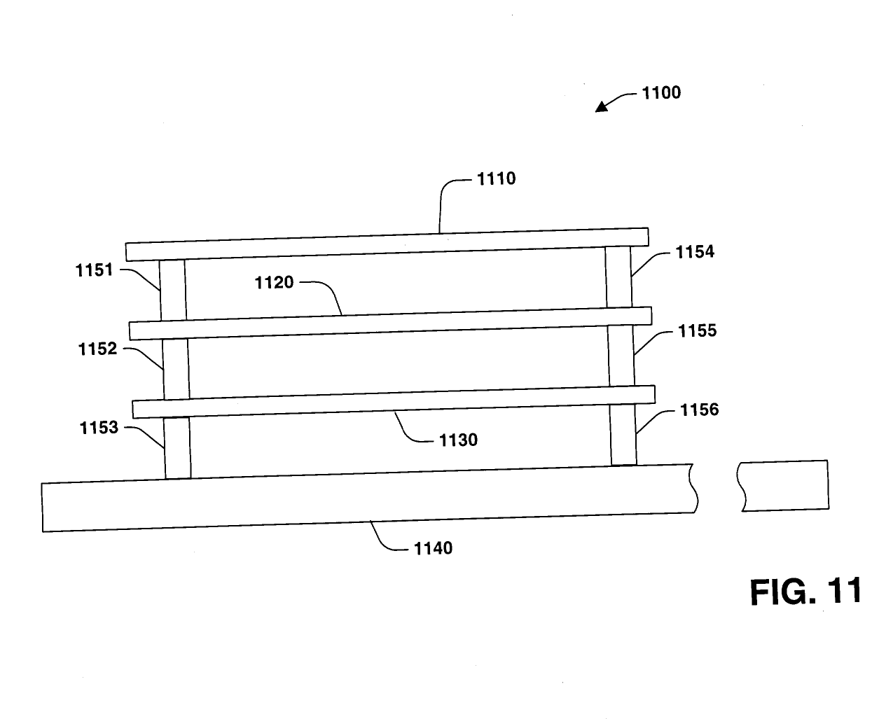

FIG. 12 graphically illustrates an exemplary opto-mounting architecture in a system 1200. The example depicts the opto-mounting system 1210 as a cylindrical medium with a physical outlining structure 1210 bounding a cylindrical inner structure—a Free Space Optical Interconnect (FSOI) 1215. The cylindrical nature of the opto-mounting system 1200 presented is not intended to limit the shape. It can be appreciated that the shape could be any three dimensional shape, for example a cube or polyhedron. In addition, the outlining physical structure 1210 and the internal FSOI 1215 may be different shapes. It can also be appreciated that other configurations are possible, for example the physical structure 1210 could reside within an external FSOI 1215, or two physical structures could exist, one internal and one external, and the FSOI 1215 could be reside between them.

The system 1200 depicts the FSOI 1215 with one or more information channels 1220. It can be appreciated that the FSOI 1215 could include only one channel, allowing information to flow in one direction. Information could be multiplexed in order to transfer several signals through one channel. In another aspect, a plurality of channels could exist, but information may only flow in one direction. In yet another aspect, the FSOI 1215 could include one channel, but allow bidirectional flow of information where information would flow consecutively, first in one direction then in the other direction. Still another aspect could entail two channels, each providing a unidirectional pathway for a multiplexed signal where information flow in the two channels is transmitted in opposite directions. It can be appreciated that the above scenarios as well as the other techniques for transferring information can be combined in a single system.

Turning to FIG. 13, a system 1300 illustrating opto-interconnects (FSOI) 1310, 1315 in accordance with the subject invention, and namely of the types discussed in FIG. 11-12, are employed to mount a PMCM expansion board 1320 to a printed wiring board (PWB) 1330. The PMCM expansion board 1320 houses one or more flip chip application specific integrated circuit (ASIC) dies 1340, 1345. Mounting in flip chip configuration includes mounting ASIC dies face down to the substrate 1360. The interface 1350, 1355 illustrates that one or more chip bumps are in contact with the substrate 1360. The ASICS 1340, 1345 can also be interconnected (not shown—electrically and/or optically) within the PMCM expansion board 1320.

The PMCM expansion board 1320 is mounted to the PWB 1330 through the FSOI 1310, 1315. The exemplary illustration employs FSOI devices that encompass a physical connecting structure and transmissions channels. Multiple PMCM expansion boards (not shown) can also communicate through a PWB 1330 interconnect (not shown).

FIG. 14 illustrates a prior art technique for mounting a daughter card 1410 to a PWB 1420. The daughter card 1410 includes a MCM (e.g., ceramic) 1430. Within the MCM 1430 package, wire bonds 1440 via pads (not shown) connect electrical circuitry 1450 to the substrate 1460. The daughter card 1410 is physically connected to the PWB 1420 through a plurality a connections, for example soldered ball bonds 1470, 1473, 1476. The plurality of soldered ball bonds 1470, 1473, 1476 provide an electrical interconnect between the daughter card 1410 and the PWB 1420

For purposes of brevity and simplicity, the following methodology is shown and described as a series of acts. It is appreciated that the present invention is not limited by the sequence or function of the acts, as some acts may, in accordance with the present invention, occur in different order and/or concurrently with other acts from that shown and described herein. Moreover, not all illustrated acts may be required to implement a methodology in accordance with the present invention.

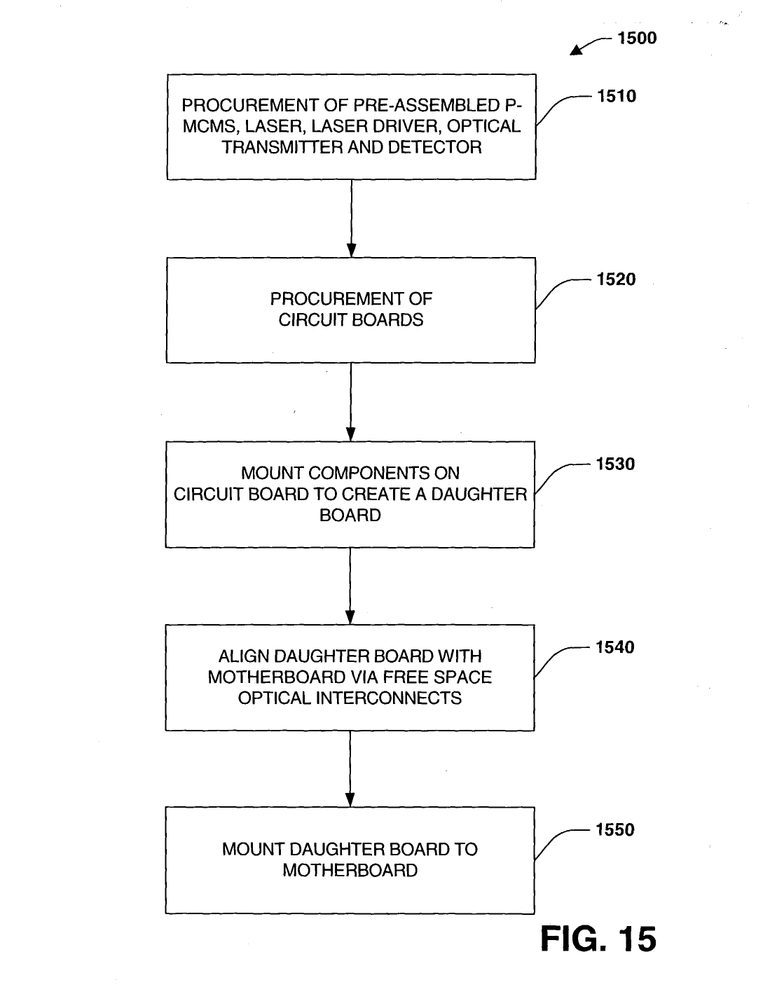

FIG. 15 illustrates an exemplary methodology 1500 for assembling a system in accordance with an aspect of the current invention. Methodology 1500 commences at 1510 with the procurement of at least a pre-assembled p-MCM, a laser, a laser driver, an optical transmitter and an optical detector. It can be appreciated that at least one pre-assembled p-MCM, laser, laser driver, optical transmitter and optical detector may be a module, independent components and/or a combination of module and independent components. Furthermore, the types and quantities of components will vary according to the application and the performance requirements. Block 1510 is not intended to limit the components, but to provide a brief example in accordance with the subject invention. In one aspect on the present invention, plastic components are utilized to reduce MCM cost, for example cost reduction from $100,000 to $5,000-$6,000 can be realized. In another aspect of the current invention, radiation hardened components may be employed.

A small circuit board (e.g., BT Laminate or the like) is obtained at 1520. The circuit board is substantially smaller than conventional mezzanine boards, for example a typical mezzanine may by 20″×26″ whereas 1″×2″ circuit boards can be used with methodology 1500. Furthermore, the weight of the small boards is substantially less than conventional mezzanine boards.

At 1530, the procured components are mounted to the BT Laminate boards to create a daughter card. This includes individual components and/or preassembled packages. Bare and/or packaged chips can be mounted with wire connections from chip pad to substrate pad. Bare chips may be fabricated in the substrate and/or mounted in flip chip configuration in order to avoid lead wires and minimize the distance between the chip and substrate. This minimizes lead wire parasitics.

The daughter card can then be aligned with the motherboard at 1540 such that its optical transmitter and optical detector correspond to complementary optical detector and optical transmitter of the motherboard. The optical interface provides the means for optically transferring data between the motherboard and the daughter card. An optical interface is advantageous because it reduces the number of electrical connections, which introduce noise, it can scale with data rates and it simplifies the installation and removal of components.

Next, the daughter card can be affixed to the motherboard through a separable mechanism at 1550. The separable mechanism improves serviceability by allowing cards, and therefore components, to be removed without the necessity of unsoldering connections.

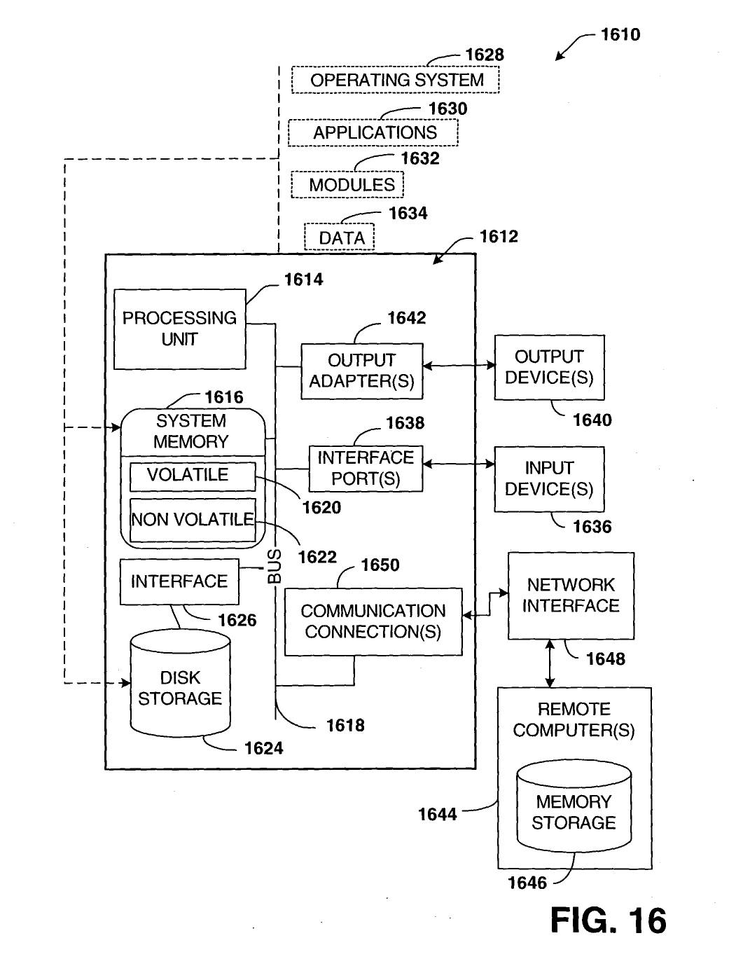

It is to be appreciated that the foregoing systems and methodologies can be employed in mainframe computers, workstations, personal computers, laptops and other devices, apparatuses and manufactures that entail signal processing. In order to provide additional context for various computer aspects of the present invention, FIG. 16 and the following discussion are intended to provide a brief, general description of a suitable operating environment 1610 in which various aspects of the present invention may be implemented.

The operating environment 1610 is only one example of a suitable operating environment and is not intended to suggest any limitation as to the scope of use or functionality of the invention. Other well known computer systems, environments, and/or configurations that may be suitable for use with the invention include but are not limited to, personal computers, hand-held or laptop devices, multiprocessor systems, microprocessor-based systems, programmable consumer electronics, network PCs, minicomputers, mainframe computers, distributed computing environments that include the above systems or devices, and the like.

With reference to FIG. 16, an exemplary environment 1610 for implementing various aspects of the invention includes a computer 1612. The computer 1612 includes a processing unit 1614, a system memory 1616, and a system bus 1618. The system bus 1618 couples system components including, but not limited to, the system memory 1616 to the processing unit 1614. The processing unit 1614 can be any of various available processors. Dual microprocessors and other multiprocessor architectures also can be employed as the processing unit 1614.

The system bus 1618 can be any of several types of bus structure(s) including the memory bus or memory controller, a peripheral bus or external bus, and/or a local bus using any variety of available bus architectures including, but not limited to, 8-bit bus, Industrial Standard Architecture (ISA), Micro-Channel Architecture (MSA), Extended ISA (EISA), Intelligent Drive Electronics (IDE), VESA Local Bus (VLB), Peripheral Component Interconnect (PCI), Universal Serial Bus (USB), Advanced Graphics Port (AGP), Personal Computer Memory Card International Association bus (PCMCIA), and Small Computer Systems Interface (SCSI).

The system memory 1616 includes volatile memory 1620 and nonvolatile memory 1622. The basic input/output system (BIOS), containing the basic routines to transfer information between elements within the computer 1612, such as during start-up, is stored in nonvolatile memory 1622. By way of illustration, and not limitation, nonvolatile memory 1622 can include read only memory (ROM), programmable ROM (PROM), electrically programmable ROM (EPROM), electrically erasable programmable ROM (EEPROM), or flash memory. Volatile memory 1620 includes random access memory (RAM), which acts as external cache memory. By way of illustration and not limitation, RAM is available in many forms such as synchronous RAM (SRAM), dynamic RAM (DRAM), synchronous DRAM (SDRAM), double data rate SDRAM (DDR SDRAM), enhanced SDRAM (ESDRAM), Synchlink DRAM (SLDRAM), and direct Rambus RAM (DRRAM).

Computer 1612 also includes removable/non-removable, volatile/nonvolatile computer storage media. FIG. 16 illustrates, for example a disk storage 1624. Disk storage 1624 includes, but is not limited to, devices like a magnetic disk drive, floppy disk drive, tape drive, Jaz drive, Zip drive, LS-100 drive, flash memory card, or memory stick. In addition, disk storage 1624 can include storage media separately or in combination with other storage media including, but not limited to, an optical disk drive such as a compact disk ROM device (CD-ROM), CD recordable drive (CD-R Drive), CD rewritable drive (CD-RW Drive) or a digital versatile disk ROM drive (DVD-ROM). To facilitate connection of the disk storage devices 1624 to the system bus 1618, a removable or non-removable interface is typically used such as interface 1626.

It is to be appreciated that FIG. 16 describes software that acts as an intermediary between users and the basic computer resources described in suitable operating environment 1610. Such software includes an operating system 1628. Operating system 1628, which can be stored on disk storage 1624, acts to control and allocate resources of the computer system 1612. System applications 1630 take advantage of the management of resources by operating system 1628 through program modules 1632 and program data 1634 stored either in system memory 1616 or on disk storage 1624. It is to be appreciated that the present invention can be implemented with various operating systems or combinations of operating systems.

A user enters commands or information into the computer 1612 through input device(s) 1636. Input devices 1636 include, but are not limited to, a pointing device such as a mouse, trackball, stylus, touch pad, keyboard, microphone, joystick, game pad, satellite dish, scanner, TV tuner card, digital camera, digital video camera, web camera, and the like. These and other input devices connect to the processing unit 114 through the system bus 1618 via interface port(s) 1638. Interface port(s) 1638 include, for example, a serial port, a parallel port, a game port, and a universal serial bus (USB). Output device(s) 1640 use some of the same type of ports as input device(s) 1636. Thus, for example, a USB port may be used to provide input to computer 1612, and to output information from computer 1612 to an output device 1640. Output adapter 1642 is provided to illustrate that there are some output devices 1640 like monitors, speakers, and printers among other output devices 1640 that require special adapters. The output adapters 1642 include, by way of illustration and not limitation, video and sound cards that provide a means of connection between the output device 1640 and the system bus 1618. It should be noted that other devices and/or systems of devices provide both input and output capabilities such as remote computer(s) 1644.

Computer 1612 can operate in a networked environment using logical connections to one or more remote computers, such as remote computer(s) 1644. The remote computer(s) 1644 can be a personal computer, a server, a router, a network PC, a workstation, a microprocessor based appliance, a peer device or other common network node and the like, and typically includes many or all of the elements described relative to computer 1612. For purposes of brevity, only a memory storage device 1646 is illustrated with remote computer(s) 1644. Remote computer(s) 1644 is logically connected to computer 1612 through a network interface 1648 and then physically connected via communication connection 1650. Network interface 1648 encompasses communication networks such as local-area networks (LAN) and wide-area networks (WAN). LAN technologies include Fiber Distributed Data Interface (FDDI), Copper Distributed Data Interface (CDDI), Ethernet/IEEE 802.3, Token Ring/IEEE 802.5 and the like. WAN technologies include, but are not limited to, point-to-point links, circuit switching networks like Integrated Services Digital Networks (ISDN) and variations thereon, packet switching networks, and Digital Subscriber Lines (DSL).

Communication connection(s) 1650 refers to the hardware/software employed to connect the network interface 1648 to the bus 1618. While communication connection 1650 is shown for illustrative clarity inside computer 1612, it can also be external to computer 1612. The hardware/software necessary for connection to the network interface 1648 includes, for exemplary purposes only, internal and external technologies such as, modems including regular telephone grade modems, cable modems and DSL modems, ISDN adapters, and Ethernet cards.

What has been described above includes examples of the present invention. It is, of course, not possible to describe every conceivable combination of components or methodologies for purposes of describing the present invention, but one of ordinary skill in the art may recognize that many further combinations and permutations of the present invention are possible. Accordingly, the present invention is intended to embrace all such alterations, modifications and variations that fall within the spirit and scope of the appended claims. Furthermore, to the extent that the term “includes” is used in either the detailed description or the claims, such term is intended to be inclusive in a manner similar to the term “comprising” as “comprising” is interpreted when employed as a transitional word in a claim.

What is claimed is:

1. A signal processing system, comprising:
a multi chip module (MCM) that is constructed with a circuit board material that houses at least one high-density I/O chip and a first optical interface; and
a main board component that includes at least a second optical interface, to facilitate movement of data between the MCM and the main board component via the first and second optical interfaces.

2. The system of claim 1, the MCM circuit board material comprises a substrate with at least one of the following attributes: high speed, compact, high reliability, low water absorption, high glass transition temperature, good thermal expansion coefficient match, and fine surface finishes.

3. The system of claim 1, the MCM circuit board comprises Bismaleimide Triazine (BT) Laminate.

4. The system of claim 1, the main board component comprises a plurality of optical wave-guides for optical on-board routing.

5. The system of claim 1, the MCM is at least one of a plastic multichip module (p-MCM), an integrated circuit (IC) module and a plastic encapsulated module (PEM).

6. The system of claim 1, the MCM further comprises a laser and an associated laser driver.

7. The system of claim 1, the MCM is constructed as at least one of a bare die fabricated into a substrate, a bare die mounted on top of a substrate and a bare die face down, employed as a flip chip, on the substrate.

8. The system of claim 1, the MCM further comprises at least one radiation-hardened component.

9. The system of claim 1, employed in at least one of a computer, device, vehicle or satellite.

10. The system of claim 1, at least one of the MCM and the main board component are employed in at least one of a hyperspectral and a multispectral imaging system.

11. The system of claim 1, the MCM is connected to and removable from the main board component through a separable mechanism.

12. The system of claim 11, the separable mechanism accommodates mounting the MCM in at least one of a vertical and a horizontal arrangement.

13. The system of claim 1, further comprising a host component for interacting with at least one of the MCM and the main board component.

14. The system of claim 1, further comprising at least one of a modulator/demodulator, a router and a computer.

15. The system of claim 1, further comprising a diagnostics component for board level diagnostics including at least one of trouble-shooting, upgrading software and firmware, retrieving board identification, revision and software release information, and logging activities.

16. The system of claim 1, further comprising a database for storing raw and processed data.

17. A data processing system, comprising:
a data processing component that is constructed with a circuit board material that houses at least one pre-assembled high I/O chip module and an optical interface;
a motherboard interface adapted to communicate with the optical interface;
an optical transceiver for communication between the data processing component and the motherboard interface.

18. The system of claim 17, the optical transceiver facilitates data transfer to the data processing board for data manipulation and data transfer to the motherboard interface after data manipulation in order to process data.

19. The system of claim 17, where the MCM circuit board material possesses at least one of the following attributes: high speed, compact, high reliability, low water absorption, high glass transition temperature, good thermal expansion coefficient match, and fine surface finishes.

20. The system of claim 17, the circuit board material comprising Bismaleimide Triazine (BT) Laminate.

21. A methodology that facilitates signal processing, comprising:
fabricating a Multi Chip Module (MCM) with at least one plastic integrated circuit component;
associating an optical interface with the MCM; and
coupling the MCM to a communications motherboard via the optical interface.

22. The method of claim 21, further comprising stacking at least two MCMs with respect to the communications motherboard.

23. The method of claim 22, further comprising associating an optical back plane with the communications motherboard.

24. The method of claim 23, further comprising communicating across the optical back plane between at least one MCM and the communications motherboard.

25. The method of claim 23, further comprising communicating between at least two MCMs across the optical backplane.

26. The method of claim 23, further comprising providing at least one optical processing component on the communications motherboard to at least one of process optical data, transmit optical data, and receive optical data.

27. The method of claim 23, further comprising providing at least one optical processing component on the MCM to at least one of process optical data, transmit optical data, and receive optical data.

28. The method of claim 27, the optical processing component utilizes optical inputs and outputs to execute instructions on the communications motherboard.

29. The method of claim 28, the optical processing component includes an optical engine to execute the instructions.

30. A communications system, comprising:
means for associating integrated circuit components in a first medium;
means for coupling the first medium to a second medium, the second medium facilitating interactions between one or more communications components; and
means for communicating optical data between the first and second medium, the optical data employed by at least one of the second medium and at least one of the communications components.
